(19) United States
(12) Patent Application Publication
(10) Pub. No.: US 2025/0133714 A1
(43) Pub. Date: Apr. 24, 2025

(54) MANAGEMENT APPARATUS AND MANAGEMENT METHOD

(71) Applicant: FUJI CORPORATION, Chiryu (JP)

(72) Inventors: Akira HARA, Toyohashi-shi (JP); Yuichi SHIMAMOTO, Toyoake-shi (JP)

(73) Assignee: FUJI CORPORATION, Chiryu (JP)

(21) Appl. No.: 18/689,214

(22) PCT Filed: Oct. 11, 2021
(86) PCT No.: PCT/JP2021/037575

§ 371 Date: Mar. 5, 2024

(51) Int. Cl. H05K 13/08

(52) U.S. Cl. CPC H05K 13/086; H05K 13/0895

(57) ABSTRACT

Provided is a management apparatus for a housing rack including multiple mounting lanes on which feeders configured to supply electronic components to an electronic component mounting machine are detachably mounted, and a lamp corresponding to each of the multiple mounting lanes, the management apparatus including: a storage section configured to store identification information of the feeder mounted on the mounting lane and maintenance information of the feeder identified by the identification information in association with each other; a specifying section configured to specify the identification information of the feeder requiring maintenance based on the maintenance information; and an output section configured to output a lighting command to the lamp corresponding to the mounting lane on which the feeder identified by the identification information specified by the specifying section is mounted.

### TECHNICAL FIELD

The present disclosure relates to a management apparatus for a housing rack in which feeders that supplies electronic components to an electronic component mounting machine are housed.

### BACKGROUND ART

Patent Literature 1 describes a housing rack in which feeders that supplies electronic components to an electronic component mounting machine are housed.

Patent Literature 1: JP-A-2016-018968

### BRIEF DESCRIPTION

### Technical Problem

An object of the present disclosure is to appropriately manage a feeder housed in a housing rack.

### Solution to Problem

In order to solve the above problems, an aspect of the present description discloses a management apparatus for a housing rack including multiple mounting lanes on which feeders configured to supply electronic components to an electronic component mounting machine are detachably mounted, and a lamp corresponding to each of the multiple mounting lanes, the management apparatus including: a storage section configured to store identification information of the feeder mounted on the mounting lane and maintenance information of the feeder identified by the identification information in association with each other; a specifying section configured to specify the identification information of the feeder requiring maintenance based on the maintenance information; and an output section configured to output a lighting command to the lamp corresponding to the mounting lane on which the feeder identified by the identification information specified by the specifying section is mounted.

Another aspect of the present description discloses a management method of a housing rack including multiple mounting lanes on which feeders configured to supply electronic components to an electronic component mounting machine are detachably mounted, and a lamp corresponding to each of the multiple mounting lanes, the management method including: a storage step of storing identification information of the feeder mounted on the mounting lane and maintenance information of the feeder identified by the identification information in association with each other; a specifying step of specifying the identification information of the feeder requiring maintenance based on the maintenance information; and a lighting step of lighting the lamp corresponding to the mounting lane on which the feeder identified by the identification information specified by the specifying step is mounted.

### Advantageous Effects

In the present disclosure, the identification information of the feeder housed in the housing rack and the maintenance information are stored in association with each other, and the identification information of the feeder requiring the maintenance is specified based on the maintenance information. Then, the lamp corresponding to the mounting lane of the feeder identified by the identification information is lighted. Accordingly, the feeder housed in the housing rack can be appropriately managed.

### BRIEF DESCRIPTION OF DRAWINGS

FIG. 1 is a perspective view illustrating an electric component mounting device.

FIG. 2 is a perspective view illustrating a tape feeder.

FIG. 3 is a block diagram illustrating a control device.

FIG. 4 is a schematic diagram illustrating a housing system.

FIG. 5 is a perspective view illustrating a housing rack.

FIG. 6 is a schematic diagram illustrating the housing system.

### DESCRIPTION OF EMBODIMENTS

Hereinafter, as an embodiment of the present disclosure, an example of the present disclosure will be described in detail with reference to drawings.

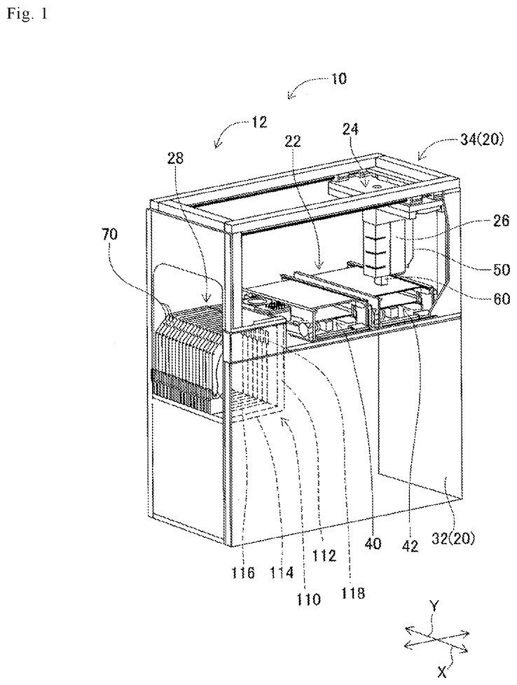

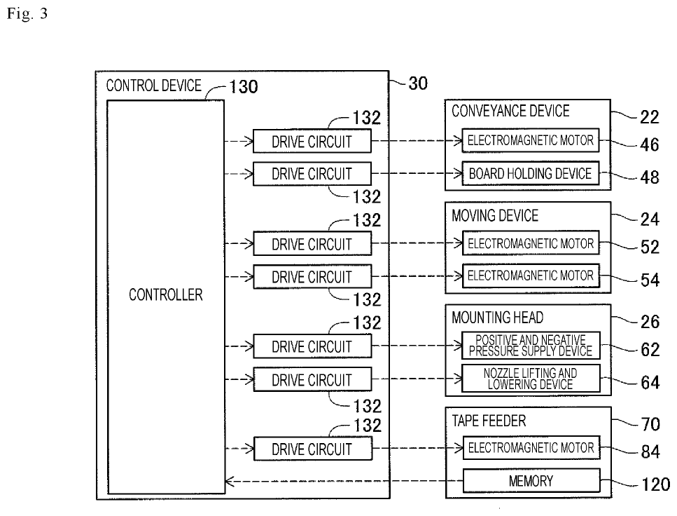

FIG. 1 illustrates electric component mounting device 10. Electric component mounting device 10 includes mounter main body 20, conveyance device 22, mounting head moving device (hereinafter, abbreviated as “moving device”) 24, mounting head 26, supply device 28, and control device (see FIG. 3) 30. Mounter main body 20 includes frame 32 and beam 34 mounted on frame 32.

Conveyance device 22 includes two conveyor devices 40 and 42. Two conveyor devices 40 and 42 are disposed on frame 32 to be parallel to each other and to extend in a predetermined direction. A direction in which conveyor devices 40 and 42 extend will be referred to as an X-axis direction, and a horizontal direction perpendicular to the X-axis direction will be referred to as a Y-axis direction. Each of two conveyor devices 40 and 42 conveys a circuit board supported at each of conveyor devices 40 and 42 in the X-axis direction with electromagnetic motor (see FIG. 3) 46. In addition, the circuit board is held by board holding device (see FIG. 3) 48 at a predetermined position.

Moving device 24 is an XY-robot-type moving device. Moving device 24 includes electromagnetic motor (see FIG. 3) 52 that slides slider 50 in the X-axis direction and electromagnetic motor (see FIG. 3) 54 that slides slider 50 in the Y-axis direction. Mounting head 26 is attached to slider 50, and mounting head 26 is moved to any position on frame 32 due to the operations of two electromagnetic motors 52 and 54.

Mounting head 26 mounts an electronic component on the circuit board. Mounting head 26 includes suction nozzle 60 provided on a lower end surface. Suction nozzle 60 communicates with positive and negative pressure supply device (see FIG. 3) 62 via negative pressure air and positive pressure air passages. Suction nozzle 60 picks up and holds the electronic component by using a negative pressure, and separates the held electronic component by using a positive pressure. In addition, mounting head 26 includes nozzle lifting and lowering device (see FIG. 3) 64 that lifts and lowers suction nozzle 60. Nozzle lifting and lowering device 64 changes a position of the electronic component held by mounting head 26 in an up-down direction.

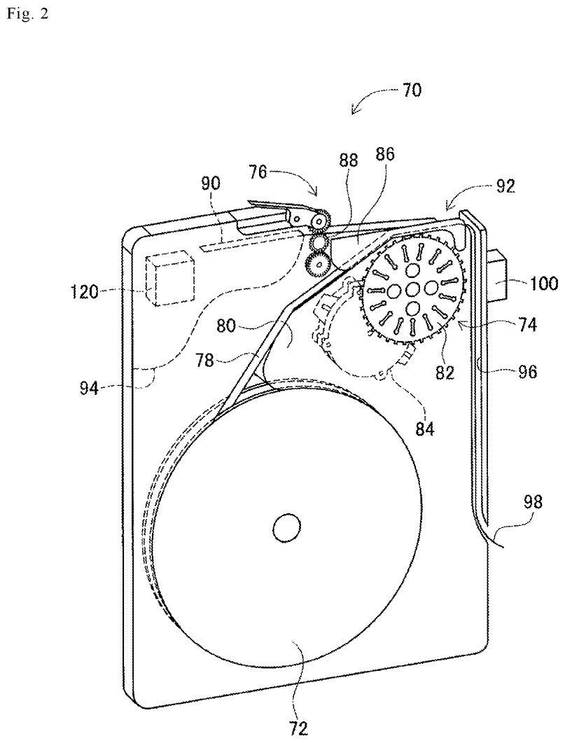

Supply device 28 is disposed at an end portion on a front side of frame 32, and includes multiple tape feeders 70. As illustrated in FIG. 2, each tape feeder 70 includes reel 72, feed-out device 74, and peeling device 76, and supplies the electronic component at an end portion of an upper surface. Specifically, taped component 78 is wound on reel 72, and taped component 78 is pulled out from reel 72 onto tape guide 80. Taped component 78 is a component in which the electronic component is taped, and feed holes (not illustrated) are formed at a predetermined pitch. Sprocket 82 of feed-out device 74 meshes with the feed hole. Sprocket 82 is rotated by electromagnetic motor 84. With such a configuration, taped component 78 is fed out toward a supply position.

In addition, peeling device 76 includes film peeling mechanism 86 and gear mechanism 88. Film peeling mechanism 86 is a mechanism for peeling top film 90 from taped component 78, and is disposed in front of opening 92 formed in an upper surface end portion of tape feeder 70. Gear mechanism 88 is a mechanism for pulling top film 90 peeled from taped component 78 into film collection section 94. With such a configuration, top film 90 is peeled from taped component 78, so that the electronic component accommodated in taped component 78 is exposed in opening 92, and the exposed electronic component is picked up and held by suction nozzle 60 of mounting head 26. That is, opening 92 is the supply position of the electronic component of tape feeder 70. Tape guide passage 96 is formed on a side surface of opening 92 in a feed-out direction of taped component 78 to be directed downward. Waste tape 98 from which the electronic component is extracted from taped component 78 is discharged through tape guide passage 96.

Connector 100 is disposed on a side surface of tape feeder 70 in the feed-out direction of taped component 78. Meanwhile, as illustrated in FIG. 1, tape feeder mounting stand 110 is disposed at the end portion on the front side of frame 32. Tape feeder mounting stand 110 includes standing surface 112 standing in a direction perpendicular to frame 32 and protruding surface 114 protruding from a lower end of standing surface 112. Multiple slide grooves 116 are formed in protruding surface 114 so as to extend in the Y direction, and connector connection portions 118 are provided in standing surface 112 so as to correspond to multiple slide grooves 116, respectively. Then, a lower end of tape feeder 70 is fitted into slide groove 116, and connector 100 of tape feeder 70 is connected to connector connection portion 118. Accordingly, tape feeder 70 is mounted on tape feeder mounting stand 110 in a positioned state and is electrically connected.

Tape feeder 70 includes memory (see FIG. 2) 120. When tape feeder 70 is mounted on tape feeder mounting stand 110 and connector 100 of tape feeder 70 is connected to connector connection portion 118 of tape feeder mounting stand 110, various information stored in memory 120 is transmitted to control device 30. The various information stored in memory 120 includes identification information of tape feeder 70. Accordingly, when connector 100 of tape feeder 70 is connected to connector connection portion 118, control device 30 recognizes the identification information of tape feeder 70 mounted on tape feeder mounting stand 110 and a mounting position of tape feeder 70.

As illustrated in FIG. 3, control device 30 includes controller 130 and multiple drive circuits 132. Multiple drive circuits 132 are connected to electromagnetic motors 46, 52, 54, and 84, board holding device 48, and positive and negative pressure supply device 62. Controller 130 includes CPU, ROM, RAM, and the like, is mainly configured as a computer, and is connected to multiple drive circuits 132. As a result, the operations of conveyance device 22, moving device 24, and the like are controlled by controller 130. Further, controller 130 is also connected to memory 120 of tape feeder 70. As a result, controller 130 acquires the identification information and the like of tape feeder 70 from tape feeder 70.

In electric component mounting device 10, with the configuration described above, mounting head 26 executes the mounting work on the circuit board held by conveyance device 22. Specifically, the circuit board is conveyed to a work position by a command from controller 130, and the circuit board is fixedly held by board holding device 48 at the work position. Tape feeder 70 feeds out the taped component to supply the electronic component at the supply position based on the command from controller 130. Then, mounting head 26 is moved to an upper side of the supply position of the electronic component by the command from controller 130, and picks up and holds the electronic component by suction nozzle 60. Then, mounting head 26 moves above the circuit board to mount the electronic component on the circuit board.

In this way, in electric component mounting device 10, the electronic component supplied from tape feeder 70 is mounted on the circuit board. In controller 130 that controls the operation of electric component mounting device 10, the number of times of supply of the electronic component supplied from each of multiple tape feeders 70 is counted for each tape feeder, and the number of times of supply of the electronic component by tape feeder 70 and the identification information of tape feeder 70 are stored in association with each other. Also in each of multiple tape feeders 70, the number of times of supply of the electronic component is counted, and the counted number of times of supply is stored in memory 120.

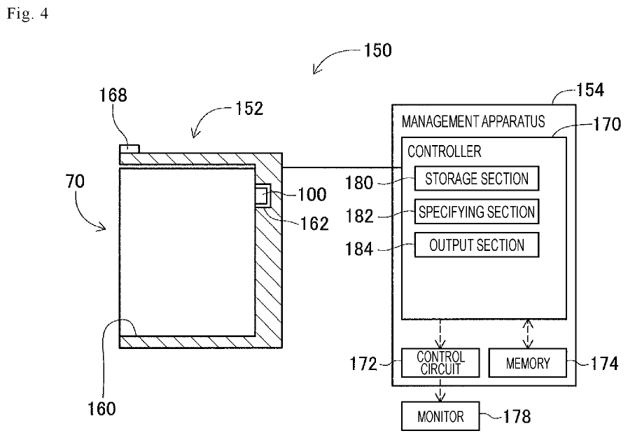

In electric component mounting device 10, basically, the tape feeder used in the mounting work is mounted on tape feeder mounting stand 110, and the tape feeder not used in the mounting work is housed in housing system 150 illustrated in FIG. 4. Housing system 150 includes housing rack 152 and management apparatus 154.

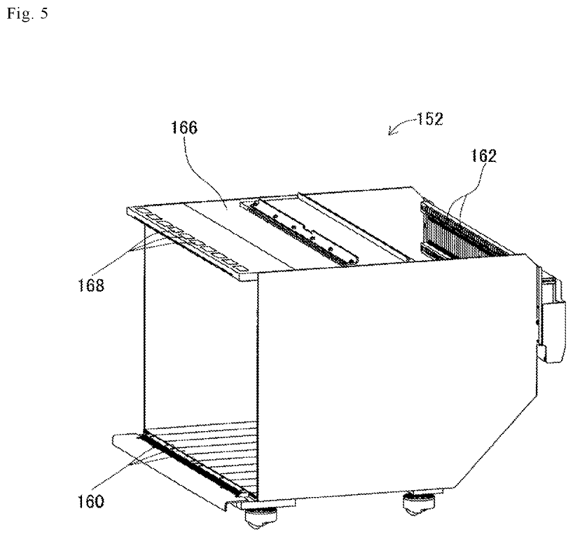

As illustrated in FIG. 5, housing rack 152 has a box shape in which a front surface is opened. A height dimension of the interior of housing rack 152 having the box shape is slightly larger than a height dimension of tape feeder 70, and a depth dimension of the interior of housing rack 152 is slightly larger than a depth dimension of tape feeder 70. A width dimension of the interior of housing rack 152 is larger than a width dimension of tape feeder 70 by N times (for example, 30 times). N tape feeders 70 can be housed in an arranged manner in housing rack 152 having such a shape. Multiple (N) slide grooves 160 are formed in a bottom surface inside housing rack 152 so as to extend in a front-rear direction. Connector connection portions 162 are disposed inside a rear surface of housing rack 152 so as to correspond to N slide grooves 160. Then, the lower end of tape feeder 70 is fitted into slide groove 160, and connector 100 of tape feeder 70 is connected to connector connection portion 162. Accordingly, tape feeder 70 is housed in housing rack 152 in a positioned state and is electrically connected. Further, LED lamp 168 is disposed on top plate 166 of housing rack 152 so as to correspond to each of multiple slide grooves 160.

As illustrated in FIG. 4, management apparatus 154 includes controller 170, control circuit 172, and memory 174. Controller 170 includes CPU, ROM, RAM, and the like, is mainly configured as a computer, and is connected to control circuit 172. Control circuit 172 is connected to monitor 178. Accordingly, any image is displayed on monitor 178 in accordance with a command from controller 170. Controller 170 is also connected to memory 174. Accordingly, controller 170 stores various information in memory 174 and acquires the various information from memory 174.

Further, controller 170 is connected to LED lamp 168 and connector connection portion 162 of housing rack 152. As a result, controller 170 transmits a lighting command to LED lamp 168 of housing rack 152, thereby lighting LED lamp 168. When tape feeder 70 is housed in housing rack 152 and connector 100 of tape feeder 70 is connected to connector connection portion 162 of housing rack 152, controller 170 acquires the identification information and the like stored in memory 120 of tape feeder 70. In this case, controller 170 detects connector connection portion 162 to which connector 100 of tape feeder 70 is connected, thereby specifying a housing position of tape feeder 70 in housing rack 152, that is, slide groove 160 in which tape feeder 70 is housed. Then, controller 170 stores the acquired identification information of tape feeder 70 and the specified housing position of tape feeder 70 in memory 174 in association with each other. Management apparatus 154 for housing system 150 and control device 30 of electric component mounting device 10 are connected to each other, and various information is transmitted and received between management apparatus 154 and control device 30.

In housing system 150, with the configuration described above, tape feeder 70 necessary for the mounting work is guided during the setup work in electric component mounting device 10. Specifically, control device 30 of electric component mounting device 10 stores information (hereinafter, referred to as “necessary component information”) indicating the type of the electronic component necessary for the mounting work. Control device 30 also stores information (hereinafter, referred to as “association information”) in which the identification information of tape feeder 70 is associated with information (hereinafter, referred to as “accommodated component information”) indicating the type of the electronic component accommodated in tape feeder 70. Then, control device 30 transmits the necessary component information and the association information to management apparatus 154.

When controller 170 of management apparatus 154 receives the necessary component information and the association information, controller 170 extracts information matching the necessary component information from the accommodated component information included in the association information. Then, controller 170 specifies the identification information of tape feeder 70 associated with the extracted accommodated component information in the association information. Subsequently, controller 170 extracts the identification information matching the specified identification information from the identification information of tape feeder 70 stored in memory 174. Next, controller 170 specifies the housing position of tape feeder 70 associated with the extracted identification information in memory 174. Then, controller 170 transmits the lighting command to LED lamp 168 corresponding to the specified housing position of tape feeder 70, that is, slide groove 160 in which tape feeder 70 is housed, thereby lighting LED lamp 168 that has received the lighting command. Accordingly, tape feeder 70 accommodating the electronic components corresponding to the necessary component information is indicated by lighting of LED lamp 168, in housing rack 152. That is, tape feeder 70 which accommodates the electronic components necessary for the mounting work during the setup work in electric component mounting device 10 is indicated by the lighting of LED lamp 168, in housing rack 152. Accordingly, an operator can easily find, in housing rack 152, tape feeder 70 that is to be mounted on electric component mounting device 10 during the setup work in electric component mounting device 10. As described above, in housing system 150, the guide of tape feeder 70 necessary for the mounting work during the setup work in electric component mounting device 10 is performed by the lighting of LED lamp 168.

In housing system 150, it is possible to execute a mode (hereinafter, referred to as “maintenance mode”) of executing the guide of tape feeder 70 requiring the maintenance work, in addition to a mode (hereinafter, referred to as “main mode”) of executing the guide of tape feeder 70 necessary for the mounting work during the setup work. Specifically, maintenance information is also stored in memory 120 of tape feeder 70. The maintenance information includes the number of times of supply of the electronic component in tape feeder 70 and a previous maintenance execution date of tape feeder 70. In housing system 150, as described above, when tape feeder 70 is housed in housing rack 152, controller 170 acquires the identification information from memory 120 of tape feeder 70 and at the same time, controller 170 also acquires the maintenance information in addition to the identification information. Therefore, controller 170 stores the maintenance information in memory 174 of management apparatus 154 in association with the identification information of the tape feeder and the housing position of tape feeder 70.

As described above, in memory 174 of management apparatus 154, the identification information, the housing position, and the maintenance information of the tape feeder are stored in association with each other for each tape feeder housed in housing rack 152. In addition, memory 174 stores an upper limit value of the number of times of supply of the electronic component in tape feeder 70 (hereinafter, referred to as “upper limit number of times of supply”) and an upper limit value of an interval at which the maintenance of tape feeder 70 is executed (hereinafter, referred to as “upper limit period”). Then, controller 170 specifies the tape feeder (hereinafter, referred to as “maintenance target feeder”) requiring the maintenance based on the maintenance information, the upper limit number of times of supply, and the upper limit period stored in memory 174.

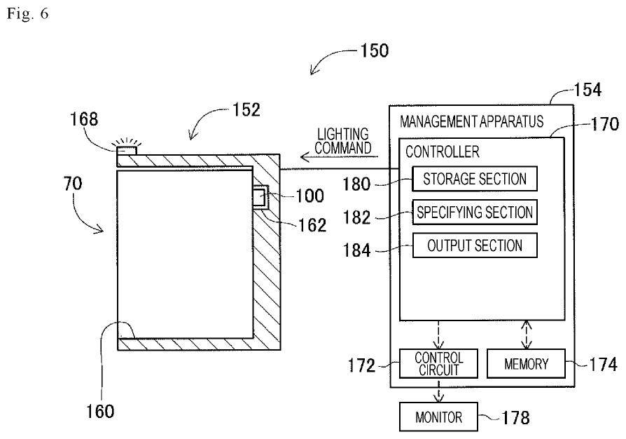

Specifically, controller 170 determines whether the number of times of supply of the electronic component included in the maintenance information exceeds the upper limit number of times of supply. When the number of times of supply of the electronic component exceeds the upper limit number of times of supply, controller 170 specifies the identification information of the tape feeder associated with the maintenance information including the number of times of supply of the electronic component. When the number of times of supply of the electronic component does not exceed the upper limit number of times of supply, controller 170 determines whether an elapsed period from the previous maintenance execution date included in the maintenance information exceeds the upper limit period. When the elapsed period from the previous maintenance execution date exceeds the upper limit period, controller 170 specifies the identification information of the tape feeder associated with the maintenance information including the previous maintenance execution date. In this manner, when controller 170 specifies the identification information of the tape feeder, controller 170 also specifies the housing position of the tape feeder associated with the specified identification information. Then, as illustrated in FIG. 6, controller 170 transmits the lighting command to the specified housing position, that is, LED lamp 168 corresponding to slide groove 160. Accordingly, LED lamp 168 corresponding to slide groove 160 in which the maintenance target feeder is housed is lighted. As described above, in the maintenance mode, the operator can easily find the maintenance target feeder in housing rack 152 by guiding the maintenance target feeder by lighting LED lamp 168. As a result, it is possible to execute the maintenance of the maintenance target feeder at an early stage, and it is possible to prevent deterioration in quality due to the execution of the mounting work using the maintenance target feeder.

In the maintenance mode, it is also possible to guide the tape feeder (hereinafter, referred to as “maintenance scheduled feeder”) requiring the maintenance not on the current day but on the next day or next week. Specifically, a period during which the operator wants to execute the maintenance is set. Then, controller 170 determines whether the number of times of supply of the tape feeder exceeds the upper limit number of times of supply within the set period. Specifically, for example, each time controller 170 acquires the maintenance information from the tape feeder, controller 170 cumulatively stores the acquired maintenance information and the date when the maintenance information is acquired, in association with each other. Then, controller 170 calculates the number of times of supply of the tape feeder per day, and estimates the number of times of supply (hereinafter referred to as “scheduled number of times of supply”) that is scheduled to reach the last day of the set period. Next, controller 170 determines whether the scheduled number of times of supply exceeds the upper limit number of times of supply. When the scheduled number of times of supply of the electronic component exceeds the upper limit number of times of supply, controller 170 specifies the identification information of the tape feeder associated with the maintenance information. When the scheduled number of times of supply of the electronic component does not exceed the upper limit number of times of supply, controller 170 determines whether a period to the last day of the set period from the previous maintenance execution date included in the maintenance information exceeds the upper limit period. When the period to the last day of the set period from the previous maintenance execution date exceeds the upper limit period, controller 170 specifies the identification information of the tape feeder associated with the maintenance information.

In this manner, when controller 170 specifies the identification information of the tape feeder, controller 170 also specifies the housing position of the tape feeder associated with the specified identification information. Then, controller 170 transmits the lighting command to the specified housing position, that is, LED lamp 168 corresponding to slide groove 160. As described above, in the maintenance mode, it is also possible to guide the maintenance scheduled feeder by lighting of LED lamp 168. Accordingly, it is possible to easily find, in housing rack 152, the tape feeder requiring the maintenance within the period desired by the operator, and to execute the maintenance of the tape feeder in accordance with the convenience of the operator.

Further, in the maintenance mode, in addition to guiding the maintenance target feeder and maintenance scheduled feeder by lighting of LED lamp 168, the guide is also performed by displaying the maintenance target feeder and the maintenance scheduled feeder on monitor 178. That is, when controller 170 specifies the identification information of the tape feeder, controller 170 displays the identification information of the tape feeder and the housing position of the tape feeder in housing rack 152 on monitor 178. Accordingly, the operator can recognize the presence or absence and the housing position of the maintenance target feeder and the maintenance scheduled feeder by checking monitor 178.

As illustrated in FIG. 6, controller 170 of management apparatus 154 includes storage section 180, specifying section 182, and output section 184. Storage section 180 is a functional unit for storing the identification information of the tape feeder and the maintenance information in memory 174 in association with each other. Specifying section 182 is a functional unit for specifying the maintenance target feeder and the maintenance scheduled feeder based on the maintenance information. Output section 184 is a functional unit for outputting the lighting command of LED lamp 168 corresponding to slide groove 160 in which the specified tape feeder is mounted. The step executed by storage section 180 is an example of a storage step. The step executed by specifying section 182 is an example of a specifying step. The step of lighting LED lamp 168 in accordance with the lighting command output by output section 184 is an example of a lighting step.

In the example described above, electric component mounting device 10 is an example of an electronic component mounting machine. Tape feeder 70 is an example of a feeder. Housing rack 152 is an example of a housing rack. Management apparatus 154 is an example of a management apparatus. Slide groove 160 is an example of a mounting lane. LED lamp 168 is an example of a lamp. Storage section 180 is an example of a storage section. Specifying section 182 is an example of a specifying section. Output section 184 is an example of an output section.

The present disclosure is not limited to the example described above, and can be carried out in various aspects to which various modifications and improvements are applied based on the knowledge of those skilled in the art. Specifically, for example, in the example described above, tape feeder 70 is adopted as the feeder housed in housing rack 152, but various feeders can be adopted. Specifically, for example, various feeders, such as a lead component feeder, a bowl feeder, a stick feeder, and a bulk feeder, can be adopted.

In the example described above, LED lamp 168 is lighted by management apparatus 154 transmitting the lighting command to housing rack 152. Alternatively, a control device may be provided in housing rack 152, management apparatus 154 may transmit the identification information of the tape feeder to the control device, and LED lamp 168 may be lighted in accordance with a command from the control device.

Although LED lamp 168 of housing rack 152 is lighted in the example described above, an LED lamp may be provided in the tape feeder and the LED lamp of the tape feeder may be lighted. In such a case, at least one of LED lamp 168 of housing rack 152 and the LED lamp of the tape feeder need only be lighted.

In the example described above, controller 170 acquires the maintenance information from memory 120 of tape feeder 70, but may acquire the maintenance information from a device different from the tape feeder, such as control device 30 of electric component mounting device 10.

In the example described above, the number of times of supply of the electronic component by the tape feeder is adopted as the maintenance information, but various information can be adopted as long as the information indicates the number of operations of the tape feeder. Specifically, for example, the number of times the electronic component supplied from the tape feeder is held by a holder or the number of times sprocket 82 of tape feeder 70 rotates can be adopted.

### REFERENCE SIGNS LIST

10: electric component mounting device (electronic component mounting machine), 70: tape feeder (feeder), 152: housing rack, 154: management apparatus, 160: slide groove (mounting lane), 168: LED lamp (lamp), 180: storage section, 182: specifying section, 184: output section

1. A management apparatus for a housing rack including multiple mounting lanes on which feeders configured to supply electronic components to an electronic component mounting machine are detachably mounted, and a lamp corresponding to each of the multiple mounting lanes, the management apparatus comprising:
a storage section configured to store identification information of the feeder mounted on the mounting lane and maintenance information of the feeder identified by the identification information in association with each other;
a specifying section configured to specify the identification information of the feeder requiring maintenance based on the maintenance information; and
an output section configured to output a lighting command to the lamp corresponding to the mounting lane on which the feeder identified by the identification information specified by the specifying section is mounted.

2. The management apparatus according to claim 1,
wherein the maintenance information includes the number of operations of the feeder, and
the specifying section is configured to, in a case where the number of operations of the feeder exceeds a threshold number, specify the identification information associated with the maintenance information.

3. The management apparatus according to claim 1,
wherein the maintenance information includes a previous maintenance execution date, and
the specifying section is configured to, in a case where an elapsed period from the previous maintenance execution date exceeds a threshold period, specify the identification information associated with the maintenance information.

4. The management apparatus according to claim 1,
wherein the specifying section is configured to specify the identification information of the feeder requiring the maintenance during a set period based on the maintenance information.

5. The management apparatus according to claim 1,
wherein the storage section is configured to acquire the identification information and the maintenance information from the feeder mounted on the mounting lane and store the identification information and the maintenance information in association with each other.

6. A management method of a housing rack including multiple mounting lanes on which feeders configured to supply electronic components to an electronic component mounting machine are detachably mounted, and a lamp corresponding to each of the multiple mounting lanes, the management method comprising:
a storage step of storing identification information of the feeder mounted on the mounting lane and maintenance information of the feeder identified by the identification information in association with each other;
a specifying step of specifying the identification information of the feeder requiring maintenance based on the maintenance information; and
a lighting step of lighting the lamp corresponding to the mounting lane on which the feeder identified by the identification information specified by the specifying step is mounted.
